(19) United States
(12) Patent Application Publication
(10) Pub. No.: US 2012/0181531 A1
(43) Pub. Date: Jul. 19, 2012

(54) SEMICONDUCTOR ELEMENT AND MANUFACTURING METHOD OF THE SAME

(75) Inventors: Ken Nakahara, Kyoto (JP); Shunsuke Akasaka, Kyoto (JP); Masashi Kawasaki, Miyagi (JP); Akira Ohtomo, Miyagi (JP); Atsushi Tsukazaki, Miyagi (JP)

(73) Assignee: ROHM CO., LTD, KYOTO (JP)

(21) Appl. No.: 12/672,432

(22) PCT Filed: Aug. 7, 2008
(86) PCT No.: PCT/JP2008/064227

§ 371 Date: Apr. 4, 2012

(30) Foreign Application Priority Data
Aug. 8, 2007 (JP) 2007-206930

(51) Int. Cl. H01L 29/227; H01L 21/36

(52) U.S. Cl. 257/43; 438/104; 257/E29.098; 257/E21.461

(57) ABSTRACT

A semiconductor element includes a semiconductor layer mainly composed of MgₓZn₁₋ₓO (0<=x<1), in which manganese contained in the semiconductor layer as impurities has a density of not more than 1×10¹⁶ cm⁻³.

### TECHNICAL FIELD

The present invention relates to a zinc oxide semiconductor element, and specifically, relates to a semiconductor element doped with acceptors and a method of manufacturing the same.

### BACKGROUND ART

In a zinc oxide (ZnO) semiconductor, an exciton which is a combination of a hole and an electron has large binding energy (60 meV). The exciton can therefore exist stably even at room temperature and can efficiently release photons having excellent monochromatic nature. Accordingly, ZnO semiconductors being increasingly applied to light emitting diodes (LED) used as light sources of illumination equipment, backlights, and the like, high-speed electron devices, surface acoustic wave devices, and the like. Herein, the “ZnO semiconductors” include ZnO-based mixed crystal materials with a part of Zn substituted with a IIA or IIB group, ZnO-based mixed crystal materials with a part of oxygen (O) substituted with a VIB group, and combinations thereof.

However, when a ZnO semiconductor including p-type impurities, which is made of, for example, MgₓZn₁₋ₓO (0<=x<1), is used as a p-type semiconductor, it is difficult to activate acceptor dopants doped into the ZnO semiconductor. The p-type semiconductor is therefore hardly obtained. With the progress in technology, p-type ZnO semiconductors have been increasingly provided, and the light emission thereof has been confirmed. However, these p-type ZnO semiconductors are limited to use of special substrates of ScAlMgO₄ and the like (for example, see Non-patent Citations 1 and 2). Accordingly, the industries demand realization of p-type ZnO semiconductor films formed on ZnO substrates.
[Non-patent Citation 1] A. Tsukazaki, at el., “Japanese Journal of Applied Physics vol. 44”, 2005, p. 643
[Non-patent Citation 2] A. Tsukazaki, at el., “Nature Materials 4”, 2005, p. 42

### DISCLOSURE OF INVENTION

### Technical Problem

However, the p-type ZnO semiconductors cannot be easily obtained even if the ZnO substrates are used. If a ZnO semiconductor includes trapping centers trapping free carriers, the trapping centers inhibit the ZnO semiconductor from being turned into p-type. Generally, transition metal often serves as trapping centers in semiconductors. The inventors found that manganese (Mn) often used for the purpose of hardening metallic materials was well introduced into ZnO. When there are many Mn atoms in a ZnO semiconductor, the ZnO semiconductor is difficult to turn into p-type. Furthermore, including many Mn atoms in the ZnO semiconductor adversely affects the light emission property in the case of using the ZnO semiconductor as a light emitting layer and the carrier transportation property.

In the light of the aforementioned problems, an object of the present invention is to provide a ZnO semiconductor element which can be easily turned into p-type without degradation in light emission property and to provide a manufacturing method thereof.

### Technical Solution

According to an aspect of the present invention, a semiconductor element is provided, including: a semiconductor layer mainly composed of MgₓZn₁₋ₓO (0<=x<1), in which manganese contained in the semiconductor layer as impurities has a density of not more than 1×10¹⁶ cm⁻³.

According to another aspect of the present invention, a method of manufacturing a semiconductor element is provided, including: mounting a substrate on a substrate holder made of a material whose density of manganese is not more than 5000 ppm; and crystal growing a semiconductor layer composed of MgₓZn₁₋ₓO (0<=x<1) on the substrate mounted on the substrate holder.

### Advantageous Effects

According to the present invention, it is possible to provide a ZnO semiconductor element which can be easily turned into p-type and whose light emitting property is not degraded and to provide a method of manufacturing the same.

### BRIEF DESCRIPTION OF DRAWINGS

FIG. 1 is a schematic view illustrating a configuration of a semiconductor element according to an embodiment of the present invention.

FIG. 2 is a schematic view for explaining a hexagonal crystal.

FIG. 3 is a schematic view showing a configuration example of an apparatus performing SIMS using quadrupole mass spectrometry.

FIG. 4 is a schematic view showing an example of a thin film deposition system manufacturing a semiconductor element according to the embodiment of the present invention.

FIG. 5 includes photographs showing results from observation of a cross-section of an oxidized Inconel plate by a SEM-EDX.

FIG. 6 includes graphs showing examples of results from SIMS analysis of MgZnO formed using a substrate holder 20 containing Mn.

FIG. 7 includes graphs for explaining the relation between secondary ion intensity of Mn and PL integrated intensity.

FIG. 8 is a graph showing an example of the result from SIMS analysis of MgZnO formed using the substrate holder 20 made of SiC.

FIG. 9 is a graph showing an example of the result from SIMS analysis of MgZnO formed using the substrate holder 20 made of Ni.

### BEST MODE FOR CARRYING OUT THE INVENTION

Next, with reference to the drawings, an embodiment of the present invention will be described. In the following description of the drawings, same or similar parts are given same of similar symbols or numbers. The drawings are schematic, and the relation between thickness and planar dimensions, the proportion of thicknesses of layers, and the like in the drawings are different from real ones. Accordingly, specific thicknesses and dimensions should be determined referring to the following description. Moreover, it is certain that some portions have different dimensional relations or different proportion among the drawings.

The following embodiment shows examples of apparatuses or methods for embodying the technical idea of the present invention and does not specify the materials, shapes, structures, arrangements, and the like of constituent components to the following ones. The technical idea of the invention can be variously modified within the scope of the claims.

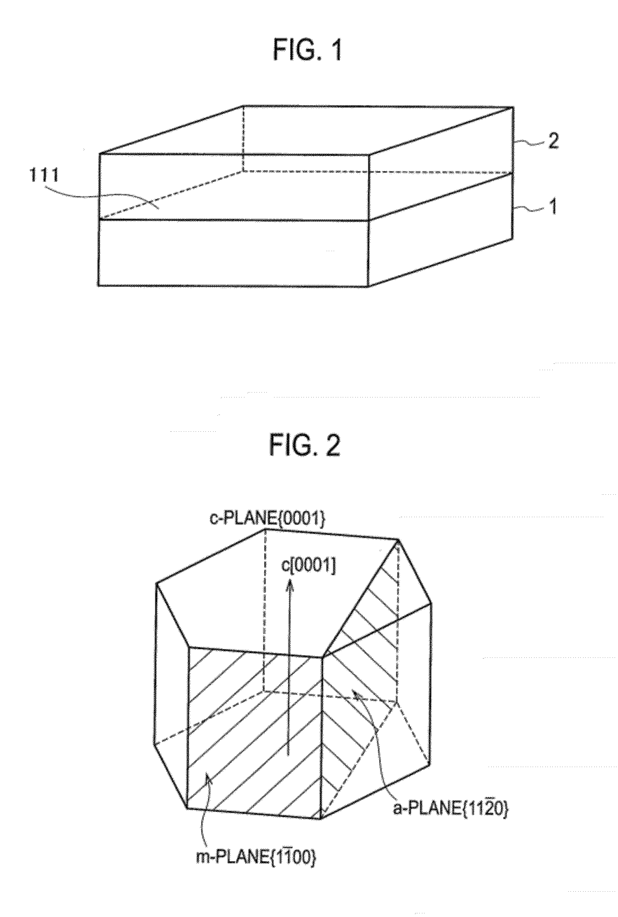

As shown in FIG. 1, a semiconductor element according to the embodiment of the present invention includes a semiconductor layer 2 mainly composed of MgₓZn₁₋ₓO (0<=x<1). Manganese (Mn) contained in the semiconductor layer 2 has a density of not more than 1×10¹⁶ cm⁻³ as impurities. The semiconductor layer 2 is composed of undoped MgₓZn₁₋ₓO or MgₓZn₁₋ₓO including n- or p-type impurities in addition to unintended impurities.

The p-type impurities contained in the semiconductor layer 2 are impurities doped into the semiconductor layer 2 as acceptors and can be nitrogen (N), copper (Cu), phosphorous (P), and the like, for example. Examples of the n-type impurities included in the semiconductor layer 2 can be aluminum (Al), group-III semiconductors of gallium (Ga), or the like.

The semiconductor layer 2 is placed on a substrate principal surface 111 of a substrate 1. The substrate 1 can be composed of Mg_{y}Zn_{1-y}O (0<=y<1), for example. The ZnO semiconductor has a hexagonal crystal structure called a wurtzite structure similarly to nitride gallium (GaN) and the like. Accordingly, the substrate 1 and semiconductor layer 2 have hexagonal crystal structures. Herein, the substrate principal surface 111 is c-plane. The principal surface of the semiconductor layer 2 formed by growing Mg_{y}Zn_{1-y}O on the substrate principal surface 111 is c-plane. FIG. 2 shows the hexagonal crystal structure. FIG. 2 is a schematic view showing a unit cell of the hexagonal crystal structure.

As shown in FIG. 2, c-axis (0001) of the hexagonal crystal extends in the axial direction of the hexagonal prism, and the plane having a normal along the c-axis (the top face of the hexagonal prism) is c-plane {0001}. The c-plane has different characteristics on the +c and −c sides and is called a polar plane. The polarization direction of the crystal of the hexagonal structure extends along the c-axis.

In the hexagonal crystal, each side face of the hexagonal prism is m-plane {1-100}, and each plane passing through a pair of edges not adjacent to each other is a-plane (11-20). m- and a-planes, which are crystalline planes perpendicular to c-plane, are orthogonal to the polarization direction and are planes with no polarity, that is, nonpolar planes.

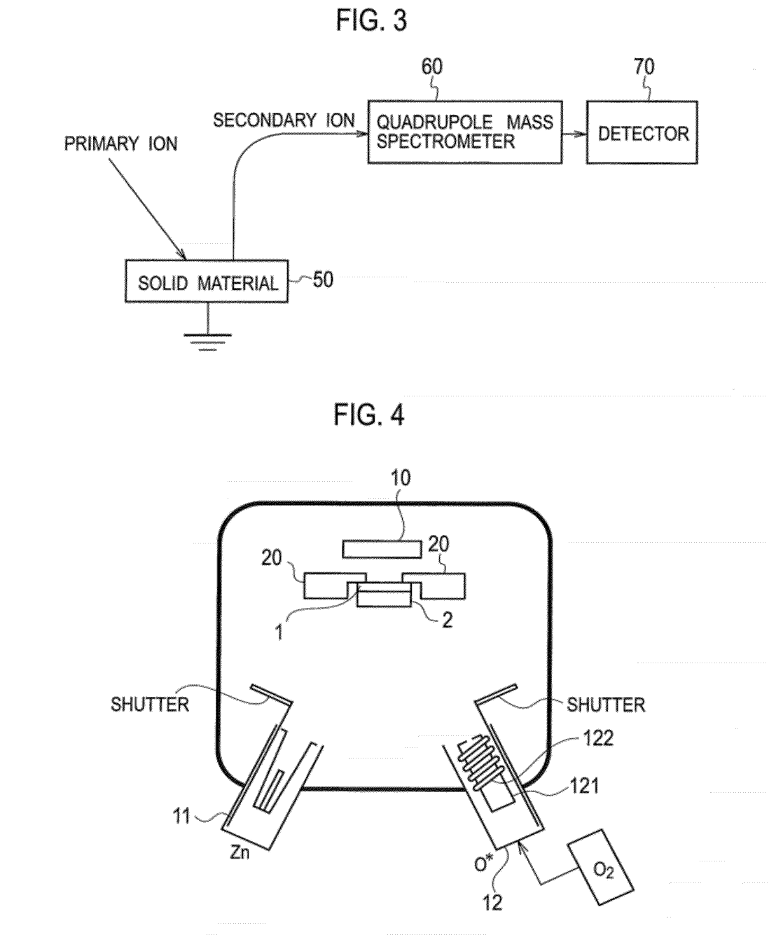

The density of Mn of the semiconductor layer 2, or the secondary ion intensity is measured by secondary ion mass spectrometry (SIMS) using quadrupole mass spectrometry, for example. FIG. 3 shows an example of the configuration of the apparatus performing SIMS using quadrupole mass spectrometry. Because of the sputtering phenomenon, substances constituting a solid sample 50 are released into vacuum from the solid sample 50 irradiated by primary ions. The released substances pass through a magnetic field. Only secondary ions having a specific mass then pass through the quadrupole mass spectrometer 60 and are incident on a detector 70 for an element analysis. In SIMS using quadrupole mass spectrometry, the energy for extracting the primary ions directly is the incident energy because the potential of a sample table on which the solid sample is placed is usually grounded. Accordingly, the acceleration energy of primary ions can be minimized for an analysis requiring high depth resolution.

As previously described, when the semiconductor layer 2 includes many Mn atoms which serve as trapping centers trapping free carriers, the semiconductor layer 2 is inhibited from being turned into p-type. Accordingly, reducing the number of Mn atoms contained in the semiconductor layer 2 facilitates turning the semiconductor layer 2 into p-type.

Currently, molecular beam epitaxy (MBE) is generally employed to form highly pure ZnO semiconductor films including MgₓZn₁₋ₓO films. The MBE uses element materials as raw materials. Accordingly, in MBE, the purities of the raw materials can be increased compared to metal organic chemical vapor deposition (MOCVD) using compound materials.

FIG. 4 shows an example of the thin film deposition system used in MBE forming the semiconductor element according to the embodiment of the present invention. The thin-film deposition system shown in FIG. 4 includes: a heat source 10 heating the substrate 1; a substrate holder 20 holding the substrate 1; and cells 11 and 12 supplying the raw materials of the semiconductor layer 2 formed on the substrate 1. The heating source 10 can be an infrared lamp or the like.

In the example shown in FIG. 4, zinc (Zn) is supplied from the cell 11. The cell 12 is a radical generator and is used in the case of applying MBE to crystal growth of compounds including gas elements such as a ZnO film. In the radical generator, normally, a high-frequency coil 122 is provided around the outside of a discharge tube 121 made of pyrolytic boron nitride (PBN) or quartz. The high-frequency coil 122 is connected to a high-frequency power supply (not shown). In the example shown in FIG. 4, oxygen (O) supplied into the cell 12 is subjected to a high frequency voltage (an electrical field) by the high-frequency coil 122, and the cell 12 thus supplies plasma particles (O*).

Generally, the substrate holder 20 can be made of Inconel, which is a nickel-based alloy having excellent heat resistance and oxidation resistance, ceramic, or the like. Stainless steel (SUS) materials which are often used for substrate holders of crystal deposition systems corrode at high temperature in crystal growth of oxides such as ZnO and therefore cannot be used in MBE forming the semiconductor element according to the embodiment of the present invention. There are many types of Inconels, but unlike SUS mainly composed of iron (Fe), Inconels are commonly composed of Ni and are alloys of Ni and Mn, aluminum (Al), chrome (Cr), iron (Fe), or the like. In order to prevent Mn contained in the substrate holder 20 from being mixed into the semiconductor layer 2 during the crystal growth and inhibiting the semiconductor layer 2 from being turned into p-type, the materials of Inconel used in the substrate holder 20 need careful attention as described later.

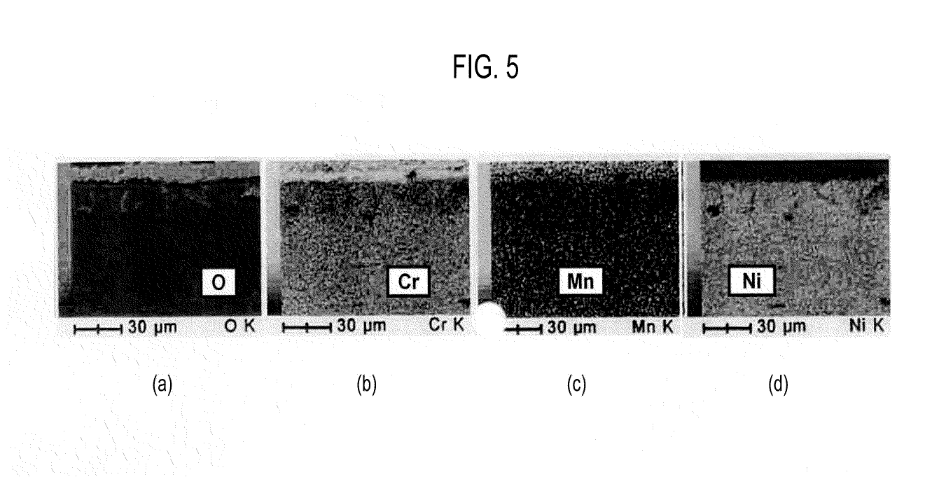

FIGS. 5(a) to 5(d) show results from observation of a cross-section of an Inconel plate which was heated to 1000° C. in the atmosphere to be oxidized until the surface thereof was blackened, the observation being performed by SEM-EDX which was a combination of a scanning electron microscope and an energy dispersive X-ray analyzer. FIGS. 5(a) to 5(d) show elements of oxygen (O), Cr, Mn, and Ni in the cross-section of the Inconel plate, respectively. The upper side of each drawing shows the surface of the Inconel plate. As shown in FIGS. 5(a) to 5(d), oxidized Cr and Mn exist in the surface of the Inconel plate. The Cr oxide is very difficult to sublime while the Mn oxide can easily sublime.

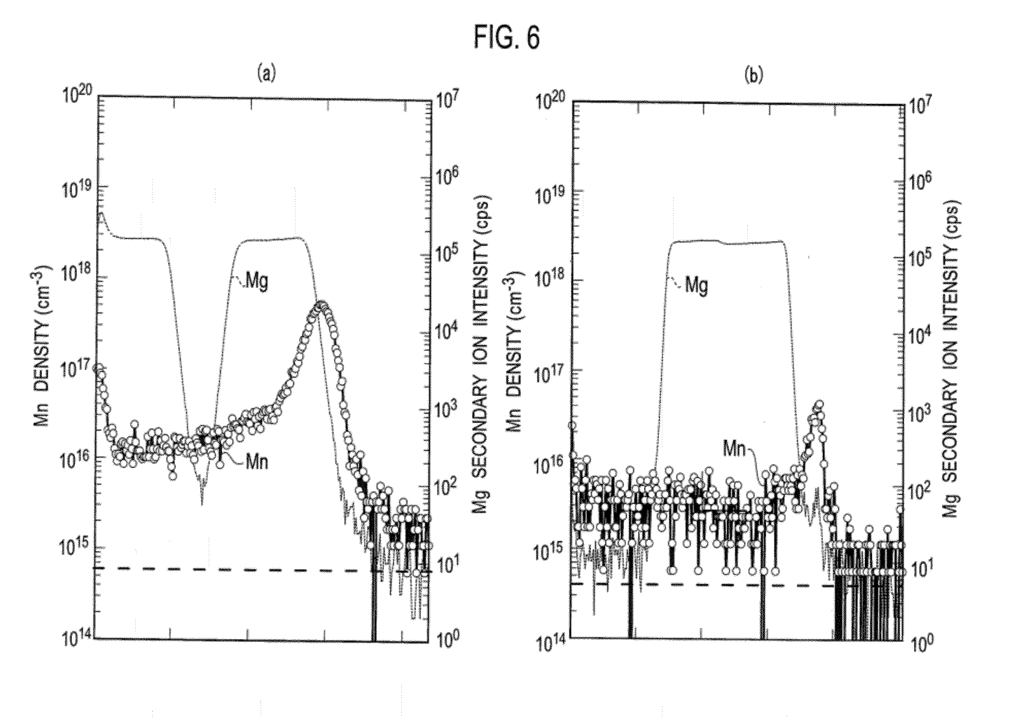

FIGS. 6(a) and 6(b) show examples of results from measurement of element concentrations and secondary ion intensity of the semiconductor layer 2 which is made of MgZnO and formed on the substrate 1 composed of ZnO using a thin-film deposition system provided with the substrate holder 20 made of Inconel containing Mn, the measurement being performed by SIMS using quadrupole mass spectrometry. FIG. 6(a) is an analysis result in the case where the temperature of the substrate holder 20 was 1043° C. with the input power of the heater used as the heating source 10 set to 740 W. FIG. 6(b) is an analysis result in the case where the temperature of the substrate holder 20 was 860° C. with the input power of the heater used as the heating source 10 set to 510 W. In FIGS. 6(a) and 6(b), data of the ZnO substrate is shown in an area with low secondary ion intensity of Mg on the right side of the graph. In the both cases of FIGS. 6(a) and 6(b), Mn densely exists between the substrate 1 and semiconductor layer 2. The higher the temperature of the substrate holder 20 is with higher input power of the heater, the higher the Mn density of the semiconductor layer 2 is. In the thin-film deposition system, the substrate holder 20 is positioned nearest to the substrate 1. Accordingly, Mn is thought to be supplied from the substrate holder 20 to the substrate 1.

In FIGS. 6(a) and 6(b), the Mn density within the film is lower than at the interface between the substrate 1 and semiconductor layer 2. This is thought to be because the Mn oxide hardly sublimes while oxygen is being supplied. For the purpose of removing moisture and the like, the substrate 1 is held by the substrate holder 20 and annealed at a temperature higher than the crystal growth temperature in vacuum before film deposition. It is therefore thought that the Mn oxide in the surface of the substrate holder 20 sublimes and adheres to the surface of the substrate 1 during the annealing.

As described above, FIGS. 5(a) to 5(d) and FIGS. 6(a) to 6(b) reveal that when Inconel containing Mn is employed for the substrate holder 20 of the thin-film deposition system shown in FIG. 4 to form the semiconductor layer 2 composed of the ZnO semiconductor on the substrate 1 by crystal growth, Mn is supplied to the semiconductor layer 2 as unintended impurities.

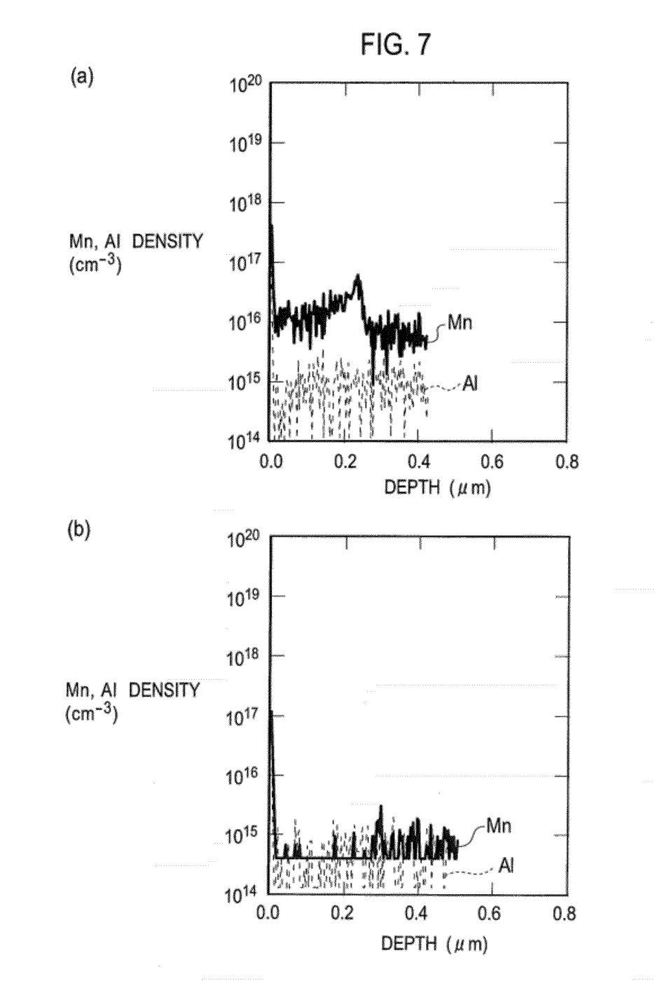

In the ZnO film including Mn mixed, carriers are deficient, and the carrier mobility, which is usually about 150 cm²/Vs, is lowered to about several tens cm²/Vs. FIGS. 7(a) and 7(b) compare samples including the semiconductor layer 2 on ZnO substrates having different densities of Mn impurities in terms of room-temperature photoluminescence (PL) integrated intensity. The PL integrated intensity herein is obtained by integrating PL intensity at room temperature in a range of 340 to 420 nm. FIGS. 7(a) and 7(b) show the secondary ion intensity of Mn and Al density of samples having PL integrated intensities of 1700 and 8300, respectively. FIGS. 7(a) and 7(b) reveal that the lower the secondary ion intensity of Mn, the higher the PL integral intensity is. In other words, as the secondary ion intensity of Mn of the semiconductor layer 2 increases, the light emitting property is degraded.

The degradation in the carrier mobility and light emitting property of the ZnO film with more Mn mixed therein indicates as described above shows that Mn serves as trapping centers of free carriers. Accordingly, in order not to degrade the light emitting property or carrier transportation property of undoped, n-, or p-type ZnO semiconductors and in order to turn the ZnO semiconductors into p-type, it is more preferable that the ZnO semiconductors contain fewer Mn atoms.

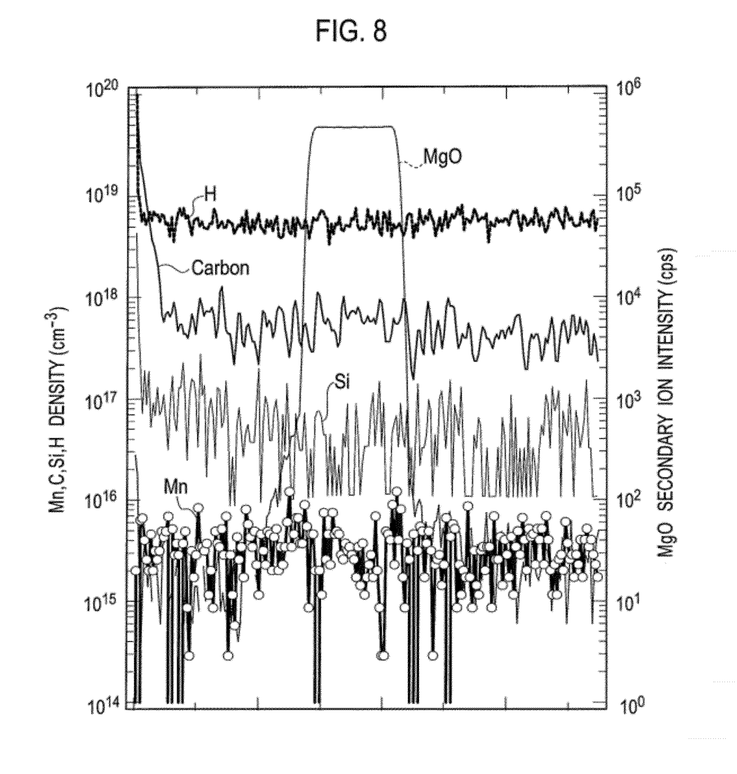

The semiconductor layer 2 composed of a ZnO semiconductor containing a reduced number of Mn atoms can be realized by employing the substrate holder 20 composed of ceramic such as silicon carbide (SiC). FIG. 8 shows an example of a result from measurement of the secondary ion intensity of the semiconductor layer 2 of the semiconductor element which is shown in FIG. 1 and is formed by a thin-film deposition system provided with the substrate holder 20 made of SiC, the measurement being performed by SIMS using quadrupole mass spectrometry. As shown in FIG. 8, the semiconductor element contains carbon (C), silicon (Si), and hydrogen (H), but the Mn density in the semiconductor element is not more than 1×10¹⁶ cm⁻³. Furthermore, there is no phenomenon of existence of Mn in high density between the substrate 1 and semiconductor layer 2 unlike the case shown in FIGS. 6(a) and 6(b). In other words, employing the substrate holder 20 made of SiC facilitates turning the semiconductor layer 2 into p-type.

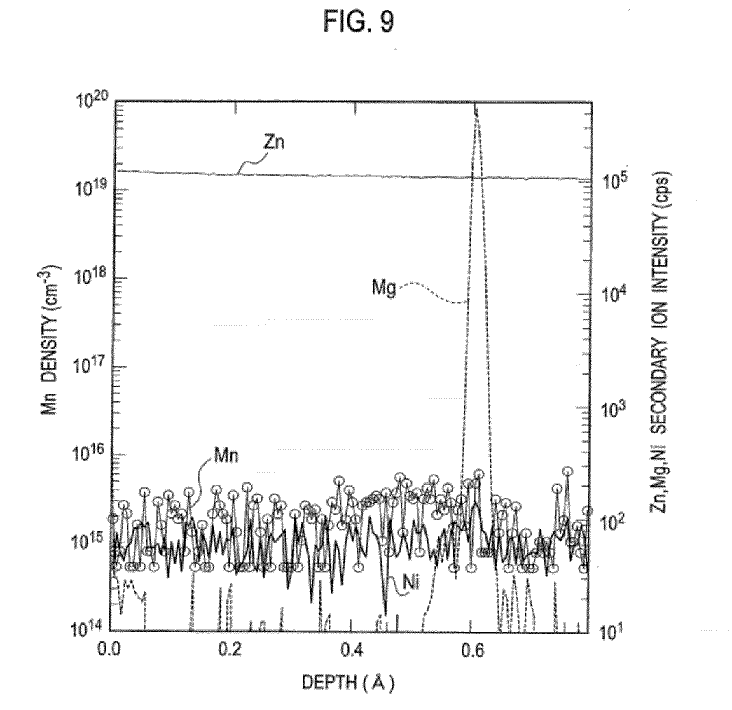

Alternatively, by employing the substrate holder 20 made of Ni which is responsible for the heat and oxidation resistances of Inconel, the semiconductor layer 2 including a reduced number of Mn atoms can be realized. As shown in FIG. 5(d), Ni contained in Inconel is hardly oxidized. FIG. 9 shows an example of the result from measurement of the densities and secondary ion intensities of the elements contained in the semiconductor layer 2 of the semiconductor element which is shown in FIG. 1 and is formed by the thin-film deposition system provided with the substrate holder 20 made of Ni, the measurement being performed by SIMS using quadrupole mass spectrometry. The secondary ion intensity of Mg in FIG. 9 takes a role of a marker indicating a boundary between the substrate 1 and semiconductor layer 2. As shown in FIG. 9, the Mn density is not more than 1×10¹⁶ cm⁻³. Furthermore, there is no phenomenon of existence of Mn in high density between the substrate land semiconductor layer 2 unlike the case shown in FIGS. 6(a) and 6(b). Accordingly, the semiconductor layer 2 can be easily turned into p-type.

In the semiconductor element according to the embodiment of the present invention, the number of Mn atoms contained in the semiconductor layer 2 as unintended impurities is controlled, and the Mn density measured by SIMS using quadrupole mass spectrometry is not more than 1×10¹⁶ cm⁻³. In other words, since the semiconductor layer 2 includes few Mn atoms serving as trapping centers trapping free carriers, the semiconductor layer 2 can be easily turned into p-type by doping acceptors of nitrogen or the like. Using the undoped, n-, or p-type semiconductor layer 2 not containing Mn, it is possible to implement illumination equipment, ultra-violet LEDs used as light sources of backlights, high-speed electronic devices including ZnO, surface acoustic wave devices, and the like.

Hereinafter, a method of manufacturing the semiconductor element shown in FIG. 1 using the thin-film deposition system provided with the substrate holder 20 made of Ni is described. The method of manufacturing the semiconductor element described below is just an example, and it is obvious that the manufacturing method can be implemented as various manufacturing methods including modifications thereof. Herein, the Mn density of the substrate holder 20 is not more than 3000 ppm.
(1) The substrate 1 which includes +c-plane as the principal surface and is composed of ZnO, for example, is etched with hydrochloric acid, washed by pure water, and then dried with dry nitrogen.
(2) The substrate 1 is set in the substrate holder 20 and is then inserted into the thin-film deposition system from a load lock chamber.
(3) The substrate 1 is heated at 900° C. for 30 min in a vacuum of 1×10⁻⁷ Pa.
(4) The temperature of the substrate is lowered to 800° C. NO gas and O₂ gas are supplied to a cell 12 to generate plasma, and the plasma is supplied together with Mg and Zn which are previously adjusted to a desired composition, thus growing the semiconductor layer 2 made of MgₓZn₁₋ₓO on the substrate 1.
(5) Subsequently, the semiconductor layer 2 is doped with p-type impurities. For example, acceptor doping using nitrogen as the p-type impurities is performed.

The aforementioned explanation shows an example employing the substrate holder 20 made of Ni. However, the substrate holder 20 made of metal or ceramic having such a low Mn density that Mn will not mixed into the semiconductor element during the crystal growth, for example, not more than 5000 ppm, more preferably not more than 3000 ppm can be used in the manufacturing of the semiconductor element according to the embodiment of the present invention. For example, the substrate holder 20 made of SiC and the like can be employed.

When the amount of nitrogen doped in MgZnO manufactured by the aforementioned method is about 5×10¹⁸ cm⁻³, a density difference N_{A}-N_{D} between the acceptor density (N_{A}) and donor density (N_{D}) of a MOS structure including MgZnO and silicon oxide (SiO₂) film stacked on ZnO measured by CV measurement is stable at about 6×10¹⁵ to 2×10¹⁶ atoms/cm³. On the other hand, in the aforementioned MOS structure including MgZnO manufactured by the thin-film deposition system provided with the substrate holder 20 made of Inconel containing Mn, the density difference N_{A}-N_{D} measured by CV measurement is 1×10¹³ to 1×10¹⁴ atoms/cm³. It is therefore thought that carriers are obviously deficient and the MgZnO includes trapping centers.

As described above, according to the method of manufacturing the semiconductor element according to the embodiment of the present invention, the semiconductor element including the semiconductor layer 2 in which the density of Mn included as unintended impurities is controlled to not more than 1×10¹⁶ cm⁻³ can be manufactured by using the thin-film deposition system provided with the substrate holder 20 containing no or a low density of Mn. The semiconductor layer 2 contains a small amount of Mn serving as the trapping centers trapping free carriers and can be therefore easily turned into p-type.

The present invention reveals that Mn serving as the trapping centers, which inhibit ZnO semiconductors from being turned into p-type, is supplied from the substrate holder 20 to the semiconductor element and shows that a semiconductor element which can be easily turned into p-type can be realized by employing the substrate holder 20 containing no or a small amount of Mn.

As described above, the present invention is described by the embodiment, but the description and drawings constituting a part of the disclosure should not be understood to limit the invention. This disclosure will show those skilled in the art various substitutive embodiments, examples, and operating techniques. It is obvious that the present invention includes various embodiments not described here. Accordingly, the technical scope of the present invention is determined only by the features of the invention according to claims proper from the above explanation.

### INDUSTRIAL APPLICABILITY

The semiconductor element of the present invention and the method of manufacturing the same are applicable to semiconductor industries and electronic device industries including manufacturer manufacturing zinc oxide semiconductor elements.

1. A semiconductor element comprising:
a semiconductor layer mainly composed of MgₓZn₁₋ₓO (0<=x<1), wherein
manganese contained in the semiconductor layer as impurities has a density of not more than 1×10¹⁶ cm⁻³.

2. The semiconductor element of claim 1, wherein the semiconductor layer includes p-type impurities.

3. The semiconductor element of claim 2, wherein the p-type impurities are nitrogen.

4. The semiconductor element of claim 1, further comprising a substrate made of Mg_{y}Zn_{1-y}O (0<=y<1), wherein
the semiconductor layer is placed on the substrate.

5. The semiconductor element of claim 1, wherein the density of manganese is a value measured by secondary ion mass spectrometry using quadrupole mass spectrometry.

6. The semiconductor element of claim 1, wherein the principal surface of the semiconductor layer is a polar plane.

7. A method of manufacturing a semiconductor element, comprising:
mounting a substrate on a substrate holder made of a material whose density of manganese is not more than 5000 ppm; and
crystal growing a semiconductor layer composed of MgₓZn₁₋ₓO (0<=x<1) on the substrate mounted on the substrate holder.

8. The method of manufacturing the semiconductor element of claim 7, wherein the substrate holder is made of nickel.

9. The method of manufacturing the semiconductor element of claim 7, wherein the substrate holder is made of silicon carbide.

10. The method of manufacturing the semiconductor element of claim 7, wherein the semiconductor layer is formed by molecular beam epitaxy.

11. The method of manufacturing the semiconductor element of claim 7, wherein the substrate is made of Mg_{y}Zn_{1-y}O(0<=y<1).

12. The method of manufacturing the semiconductor element of claim 7, further comprising:
doping p-type impurities into the semiconductor layer.

13. The method of manufacturing the semiconductor element of claim 12, wherein the p-type impurities are nitrogen.
